(19) United States
(12) Patent Application Publication
(10) Pub. No.: US 2025/0046776 A1
(43) Pub. Date: Feb. 6, 2025

(54) PACKAGING STRUCTURE AND PACKAGING METHOD

(71) Applicant: SEMICONDUCTOR MANUFACTURING INTERNATIONAL (SHANGHAI) CORPORATION, Shanghai (CN)

(72) Inventor: Jisong JIN, Shanghai (CN)

(73) Assignee: SEMICONDUCTOR MANUFACTURING INTERNATIONAL (SHANGHAI) CORPORATION, Shanghai (CN)

(21) Appl. No.: 18/790,726

(22) Filed: Jul. 31, 2024

(30) Foreign Application Priority Data
Aug. 2, 2023 (CN) 202310967777.4

(51) Int. Cl. H01L 25/18; H01L 23/00; H01L 23/31; H01L 23/538; H10B 80/00

(52) U.S. Cl. CPC H01L 25/18; H01L 23/3135; H01L 23/538; H01L 24/16; H01L 24/17; H01L 24/73; H01L 24/81; H10B 80/00; H01L 24/13; H01L 24/32; H01L 2224/13111; H01L 2224/16146; H01L 2224/16225; H01L 2224/1703; H01L 2224/32145; H01L 2224/32225; H01L 2224/73204; H01L 2224/81005; H01L 2224/81986; H01L 2225/06513; H01L 2225/06517; H01L 2225/06541; H01L 2924/1431; H01L 2924/1436

(57) ABSTRACT

This disclosure relates to a packaging structure and a packaging method. The packaging method includes: providing a bearing substrate, including a bearing face; providing a first chip, including a first face and a second face that is opposite to the first face; providing a chipset, where the chipset includes a third face and a fourth face opposite to the third face, and the chipset includes a plurality of second chips stacked in a direction perpendicular to the bearing substrate, and is electrically connected between adjacent second chips in the direction perpendicular to the bearing substrate; attaching the first chip onto the bearing substrate; attaching the chipset onto the bearing substrate; providing an interconnect chip, where the interconnect chip includes a bonding face and a back face facing away from the bonding face; bonding the interconnect chip on the first chip and the chipset.

### CROSS REFERENCE TO RELATED APPLICATIONS

This application is based on and claims priority to Chinese Patent Application No. 202310967777.4, filed on Aug. 2, 2023, the entire content of which is incorporated herein by reference.

### TECHNICAL FIELD

The present disclosure relates to the field of semiconductor packaging, and in particular relates to a packaging structure and a packaging method.

### BACKGROUND

For the size of a single chip, conventional chip manufacturing technologies are being pushed to their limits. However, an application is desired for the ability of implementing a large-sized integrated circuit by using a latest technology, and it is a great challenge for implementing high-speed and small-footprint interconnection between chips.

A conventional technique is to use a relatively smaller integrated circuit embedded in a Si bridge chip in a Si base to enable chip-to-chip interconnection by the Si bridge chip, thus providing heterogeneous chip packaging.

However, the performance of a conventional packaging structure still needs to be improved.

### SUMMARY

The present disclosure relates to a packaging structure and a packaging method for optimizing a performance of the packaging structure.

In an aspect of the disclosure, a packaging structure is provided. The packaging structure may include: a first chip, including a first face and a second face that is opposite to the first face; a chipset, where the chipset is located on a side portion of the first chip, includes a plurality of second chips stacked in a vertical direction, and is electrically connected between adjacent second chips in the vertical direction; and the chipset includes a third face and a fourth face that is opposite to the third face, and the first face and the third face face a same direction; and an interconnect chip, where the interconnect chip includes a bonding face and a back face facing away from the bonding face, the interconnect chip is located on the first chip and the chipset, the bonding face is opposite to the second face and the fourth face, and the interconnect chip is electrically connected to the chipset and the first chip; and the back face of the interconnect chip is thinned.

In an implementation, the packaging structure further includes a packaging layer, the packaging layer being located on side portions of the first chip and the chipset, and covering side walls of the first chip and the chipset.

In an implementation, the interconnect chip includes a substrate layer and an interconnect structural layer located on the substrate layer, where one face of the substrate layer facing away from the interconnect structural layer is used as the back face, and one face of the interconnect structural layer facing away from the substrate layer is used as the bonding face; or, the interconnect chip only includes an interconnect structural layer, where one face of the interconnect structural layer opposite to the first chip and the chipset is used as the bonding face, and one face of the interconnect structural layer facing away from the first chip and the chipset is used as the back face.

In an implementation, the interconnect structural layer is a rewiring structural layer.

In an implementation, the interconnect chip has a thickness of 2 μm to 15 μm.

In an implementation, the packaging structure further includes: first conductive bumps, located between the first chip and the interconnect chip and between the chipset and the interconnect chip.

In an implementation, the packaging structure further includes: second conductive bumps, where the second conductive bumps are located on the second face and the fourth face exposed from the interconnect chip, and are electrically connected to the first chip and the chipset respectively, and the height of the second conductive bump is equal to or greater than that of the back face of the interconnect chip.

In an implementation, the first chip is a logic chip, and the chipset is a high bandwidth memory chipset.

In another aspect of the disclosure, a packaging method is provided. The packaging method may include: providing a bearing substrate, where the bearing substrate includes a bearing face; providing a first chip, including a first face and a second face that is opposite to the first face; providing a chipset, where the chipset includes a third face and a fourth face that is opposite to the third face, and the chipset includes a plurality of second chips stacked in a direction perpendicular to the bearing substrate, and is electrically connected between adjacent second chips in the direction perpendicular to the bearing substrate; attaching the first chip onto the bearing substrate, where the first face is opposite to the bearing face; attaching the chipset onto the bearing substrate, where the third face is opposite to the bearing face; providing an interconnect chip, where the interconnect chip includes a bonding face and a back face facing away from the bonding face; bonding the interconnect chip on the first chip and the chipset, where the bonding face is opposite to the second face and the fourth face, and the interconnect chip is electrically connected to the chipset and the first chip; and after bonding the interconnect chip on the first chip and the chipset, thinning the back face of the interconnect chip.

In an implementation, in a step of providing an interconnect chip, the interconnect chip includes a substrate layer and an interconnect structural layer located on the substrate layer, one face of the substrate layer facing away from the interconnect structural layer is used as the back face, and one face of the interconnect structural layer facing away from the substrate layer is used as the bonding face; and in a step of thinning the back face of the interconnect chip, the substrate layer is thinned.

In an implementation, in a step of thinning the substrate layer, the substrate layer is removed, or the substrate layer is removed for a partial thickness.

In an implementation, the interconnect structural layer is a rewiring structural layer.

In an implementation, the packaging method further includes: forming a packaging layer on the bearing face on side portions of the first chip and the chipset after attaching the first chip onto the bearing substrate and attaching the chipset onto the bearing substrate, and before bonding the interconnect chip on the first chip and the chipset, the packaging layer covering side walls of the first chip and the chipset, and the second face and the fourth face being exposed; and in a step of bonding the interconnect chip on the first chip and the chipset, the interconnect chip is bonded on the first chip, the chipset, and the packaging layer.

In an implementation, a step of bonding the interconnect chip on the first chip and the chipset includes: forming first conductive bumps between the first chip and the interconnect chip and between the chipset and the interconnect chip, and bonding the first chip and the interconnect chip and bonding the chipset and the interconnect chip by the first conductive bumps.

In an implementation, the back face of the interconnect chip is thinned by employing an etching process.

In an implementation, after the back face of the interconnect chip is thinned, the remaining interconnect chip has a thickness of 2 μm to 15 μm.

In an implementation, the packaging method further includes: removing the bearing substrate after the thinning.

In an implementation, the packaging method further includes: forming second conductive bumps on the second face and the fourth face exposed from the interconnect chip after the thinning and before removing the bearing substrate, where the second conductive bumps are electrically connected to the first chip and the chipset respectively, and a height of the second conductive bump is equal to or greater than that of the back face of the interconnect chip.

In an implementation, the packaging method further includes: providing a packaging substrate; and after removing the bearing substrate, bonding the second face of the first chip and the fourth face of the chipset onto the packaging substrate.

In an implementation, the first chip is a logic chip, and the chipset is a high bandwidth memory chipset.

Compared with the prior art, the implementations of the present disclosure have the following advantages:

In the packaging structure provided in the implementations of the present disclosure, an interconnect chip is arranged in the packaging structure. The interconnect chip includes a bonding face and a back face facing away from the bonding face, the interconnect chip is located on a first chip and a chipset, the bonding face is opposite to a second face and a fourth face, and the interconnect chip is electrically connected to the chipset and the first chip, thereby electrically connecting the chipset and the first chip by the interconnect chip. Moreover, the back face of the interconnect chip is thinned, thereby reducing a thickness of the interconnect chip, which is conducive to simplifying the packaging structure and thinning of a device, and after the packaging structure is bonded onto a packaging substrate, the interconnect chip is thinner, which is conducive to shortening the distance between the first chip and the packaging substrate and the distance between the chipset and the packaging substrate, thus facilitating heat dissipation of the packaging structure and improving the performance of the packaging structure.

In the packaging method provided in the implementations of the present disclosure, the interconnect chip is bonded on the first chip and the chipset, the bonding face is opposite to the second face and the fourth face, and the interconnect chip is electrically connected to the chipset and the first chip, thereby electrically connecting the chipset and the first chip by the interconnect chip. Moreover, after the interconnect chip is bonded on the second face and the fourth face, the back face of the interconnect chip is also thinned, thereby reducing the thickness of the interconnect chip, which is conducive to simplifying the packaging structure and thinning of a device, and after the packaging structure is subsequently bonded onto the packaging substrate, the interconnect chip is thinner, which is conducive to shortening the distance between the first chip and the packaging substrate and the distance between the chipset and the packaging substrate, thus facilitating heat dissipation of the packaging structure and improving the performance of the packaging structure.

### BRIEF DESCRIPTION OF THE DRAWINGS

FIG. 1 is a schematic structural diagram of the packaging structure according to an implementation of the present disclosure; and

FIG. 2 to FIG. 13 are schematic structural diagrams corresponding to steps of a packaging method in an implementation of the present disclosure.

### DETAILED DESCRIPTION

As discussed in the background, the performance of a current packaging structure needs to be improved.

In order to address the technical problem, implementations of the present disclosure provide a packaging structure, and an interconnect chip is further arranged therein. The interconnect chip includes a bonding face and a back face facing away from the bonding face, the interconnect chip is located on a first chip and a chipset, the bonding face is opposite to a second face and a fourth face, and the interconnect chip is electrically connected to the chipset and the first chip, thereby electrically connecting the chipset and the first chip by the interconnect chip. Moreover, the back face of the interconnect chip is thinned, thereby reducing a thickness of the interconnect chip, which is conducive to simplifying the packaging structure and thinning of a device, and after the packaging structure is bonded onto a packaging substrate, the interconnect chip is thinner, which is conducive to shortening the distance between the first chip and the packaging substrate and the distance between the chipset and the packaging substrate, thus facilitating heat dissipation of the packaging structure and improving the performance of the packaging structure.

Implementations of the present disclosure further provide a packaging method. An interconnect chip is bonded on a first chip and a chipset, the bonding face is opposite to a second face and a fourth face, and the interconnect chip is electrically connected to the chipset and the first chip, thereby electrically connecting the chipset and the first chip by the interconnect chip. Moreover, after the interconnect chip is bonded on the second face and the fourth face, the back face of the interconnect chip is also thinned, thereby reducing the thickness of the interconnect chip, which is conducive to simplifying the packaging structure and thinning of a device, and after the packaging structure is subsequently bonded onto the packaging substrate, the interconnect chip is thinner, which is conducive to shortening the distance between the first chip and the packaging substrate and the distance between the chipset and the packaging substrate, thus facilitating heat dissipation of the packaging structure and improving the performance of the packaging structure.

In order to make the above objectives, features, and advantages of the implementations of the present disclosure more obvious and understandable, a detailed explanation of the specific implementations of the present disclosure will be provided below in conjunction with the accompanying drawings.

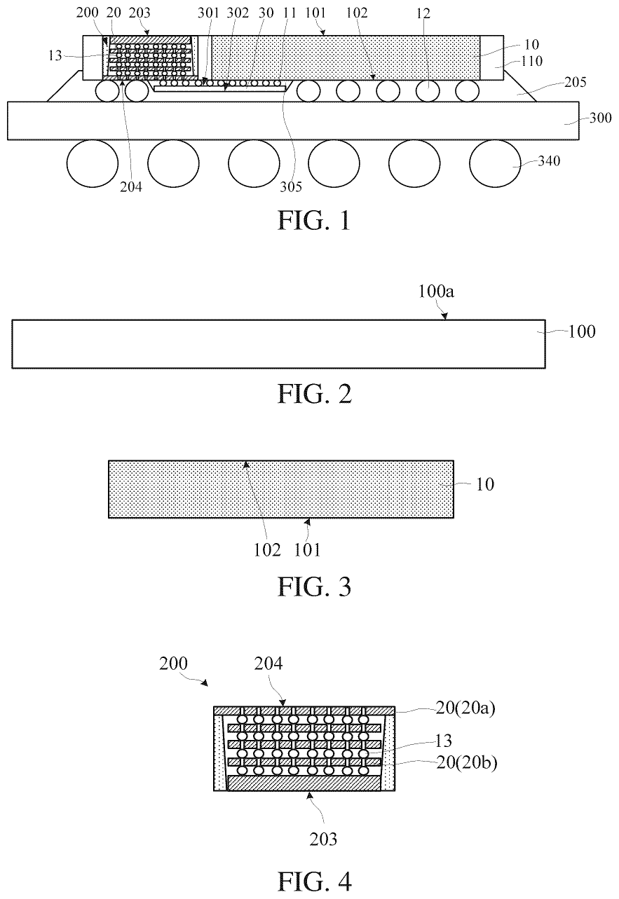

Referring to FIG. 1, a schematic structural diagram of an implementation of the packaging structure of the present disclosure is shown.

As shown in FIG. 1, in this implementation, the packaging structure includes: a first chip 10, including a first face 101 and a second face 102 that is opposite to the first face 101; a chipset 200, where the chipset 200 is located on a side portion of the first chip 10, includes a plurality of second chips 20 stacked in a vertical direction, and is electrically connected between adjacent second chips 20 in the vertical direction; and the chipset 200 includes a third face 203 and a fourth face 204 that is opposite to the third face 203, and the first face 101 and the third face 203 face a same direction; and an interconnect chip 30, where the interconnect chip 30 includes a bonding face 301 and a back face 302 facing away from the bonding face 301, the interconnect chip 30 is located on the first chip 10 and the chipset 200, the bonding face 301 is opposite to the second face 102 and the fourth face 204, and the interconnect chip 30 is electrically connected to the chipset 200 and the first chip 10; and the back face 302 of the interconnect chip 30 is thinned.

The first chip 10 is configured to be electrically connected to the chipset 200 by the interconnect chip 30 to implement packaging integration with the chipset 200.

In this implementation, the first chip 10 is a first logic chip, configured to perform logic control over the chipset 200. Specifically, the first logic chip may be a central processing unit (CPU) chip, a graphics processing unit (GPU) chip, or a system on chip (SoC) chip.

In this implementation, the first face 101 is a back face of the first chip 10, and the second face 102 is a front face of the first chip 10. The front face of the first chip 10 refers to a face that a device in the first chip 10 faces, and the back face of the first chip 10 refers to a face that the device in the first chip 10 faces away from.

In this implementation, one or more metal layers (not shown in the figure) are formed on the front face of the first chip 10 in order that the interconnect chip 30 is bonded on the first chip 10 and the chipset 200. The bonding face 301 of the interconnect chip 30 is opposite to the second face 102, and the interconnect chip 30 can be electrically connected to the first chip 10 by the metal layer(s) on the second face 102 of the first chip 10.

The chipset 200 is configured to be bonded with the interconnect chip 30, and thus, the chipset 200 and the first chip 10 are electrically connected by the interconnect chip 30, thereby forming a corresponding packaging structure to implement corresponding functions.

Specifically, in this implementation, the fourth face 204 is configured to be bonded with the interconnect chip 30, thus electrically connecting the chipset 204 and the interconnect chip.

In this implementation, the first face 101 and the third face 203 face a same direction, and thereby, the second face 102 and the fourth face 204 face a same direction in order that the interconnect chip 30 can be bonded onto the second face 102 and the fourth face 204.

In this implementation, in the chipset 200, a plurality of second chips 20 stacked in a longitudinal direction constitute a high bandwidth memory (HBM) structure. The HBM structure is employed, which is conducive to meeting the requirements for a higher information transmission rate.

In this implementation, adjacent second chips 20 in the vertical direction are electrically connected, thereby implementing electrical integration with the second chips 20. In this implementation, the vertical direction refers to a direction perpendicular to the second chip 20, the third face 203, and the fourth face 204.

Specifically, in this implementation, third conductive bumps 13 are formed between adjacent second chips 20 in the vertical direction, and the adjacent second chips 20 are electrically connected by the third conductive bumps 13.

In this implementation, materials of the third conductive bump 13 include one or more of tin, copper, aluminum, tungsten, cobalt, nickel, titanium, tantalum, titanium nitride, and tantalum nitride. In an example, the material of the third conductive bump 13 is tin.

In this implementation, in the chipset 200, the second chip 20 closest to the fourth face 204 is used as a bottom chip 20a, and the remaining second chips 20 is used as top chips 20b.

Correspondingly, in this implementation, in the chipset 200, the bottom chip 20a is bonded with the interconnect chip 30, and thereby, the bottom chip 20a is electrically connected to the interconnect chip 30. Moreover, adjacent second chips 20 are electrically connected, and thereby, the top chip 20b can be electrically connected to the interconnect chip 30 by the bottom chip 20a.

In this implementation, the bottom chip 20a is a second logic chip, configured to control the top chips 20b.

In this implementation, the top chip 20b is a storage chip, e.g., a DRAM chip. In this implementation, the quantity of the top chips 20b may be one or more. In this implementation, it is illustrated with the quantity of the top chips 20b being four. In other implementations, the top chips may also be in other quantities.

Specifically, in this implementation, the bottom chip 20a is used as a logic control chip in the chipset 200, thereby controlling the storage chip.

In this implementation, the packaging structure further includes a packaging layer 110. The packaging layer 110 is located on side portions of the first chip 10 and the chipset 200, and covers side walls of the first chip 10 and the chipset 200.

The packaging layer 110 is configured to implement packaging integration between the first chip 10 and the chipset 200. The packaging layer 110 may also play a role of insulation, sealing, and moisture proofing, which is conducive to improving the reliability of the packaging structure. The packaging layer 110 is further configured to provide a process platform for bonding the interconnect chip 30.

The second face 102 and the fourth face 204 are exposed from the packaging layer 110 in order that the interconnect chip 30 can be bonded on the second face 102 of the first chip 10 and the fourth face 204 of the chipset 200, so that the interconnect chip 30 is electrically connected to the first chip 10, and the interconnect chip 30 is electrically connected to the chipset 200, thus electrically connecting the first chip 10 and the chipset 200 by the interconnect chip 30.

As an implementation, a material of the packaging layer 110 is a molding material, e.g., epoxy resin. The epoxy resin has the advantages such as low shrinkage, good adhesion, good corrosion resistance, excellent electrical performance, and low cost. In other implementations, other suitable packaging materials may also be selected for the packaging layer.

The interconnect chip 30 is used as a bridge, configured to interconnect the first chip 10 and the chipset 200.

In this implementation, the interconnect chip 30 is bonded onto partial top faces of the first chip 10 and the chipset 200 adjacent to the first chip 10, that is, a partial surface of the second face 102 and a partial surface of the fourth face 204 are also exposed from the interconnect chip 30 in order that the second face 102 and the fourth face 204 exposed from the interconnect chip 30 are bonded with the packaging substrate, thus electrically connecting the first chip 10 and the packaging substrate and electrically connecting the chipset 200 and the packaging substrate.

More specifically, the second face 102 and the fourth face 204 exposed from the interconnect chip 30 are configured to arrange second conductive bumps 12 in order that the second face and the fourth face are bonded with the packaging substrate by the second conductive bumps 12.

The bonding face 301 is configured to be bonded with the first chip 10 and the chipset 200, and thus, the first chip 10 and the chipset 200 are electrically connected by the interconnect chip 30.

The back face 302 is thinned in order to thin the thickness of the interconnect chip 30.

In this implementation, the interconnect chip 30 includes a substrate layer (not shown in the figure) and an interconnect structural layer (not shown in the figure) located thereon. One face of the substrate layer facing away from the interconnect structural layer is used as the back face 302, and one face of the interconnect structural layer facing away from the substrate layer is used as the bonding face 301.

In this implementation, the substrate layer is configured to provide support for the formation of an interconnect structural layer, and one face of the substrate layer facing away from the interconnect structural layer is used for thinning, thereby thinning the thickness of the interconnect chip 30 while it is guaranteed that the interconnect chip 30 implements interconnect performance between the first chip 10 and the chipset 200.

That is, during the formation process of the packaging structure, when the back face 302 of the interconnect chip 30 is thinned, the substrate layer is removed only for a partial thickness to reduce the probability of damage to the interconnect structural layer, thus reducing process risks.

In this implementation, a material of the substrate layer is silicon.

The interconnect structural layer is configured to electrically connect the first chip 10 and the chipset 200.

In an example, the interconnect structural layer is a rewiring structural layer. The rewiring structural layer can redistribute a connection end of the interconnect chip in order that first conductive bumps with density and position that meets the process requirements are formed, in order that the first chip 10 and the interconnect chip 30 are electrically connected as well as the chipset 200 and the interconnect chip 30 by the first conductive bumps. Moreover, the spacing between the first conductive bumps is relatively small and the density is relatively high, which is conducive to improving the interconnect performance between the first chip 10 and the interconnect chip 30 and the interconnect performance between the chipset 200 and the interconnect chip 30, thus improving the interconnect performance between the first chip and the chipset 200.

Correspondingly, in this implementation, the interconnect structural layer is also configured to provide a process platform for the formation of first conductive bumps.

Specifically, the rewiring structural layer may include one or more rewiring layers. Specifically, a material of the rewiring layer is a conductive material. In an example, a material of the rewiring structure layer is metal, including any one or more of copper, titanium, aluminum, gold, nickel, iron, tin, silver, zinc, or chromium.

In other implementations, the substrate layer can also be completely thinned and removed to further reduce the thickness of the interconnect chip, so that only the interconnect structural layer is retained in the interconnect chip, thereby guaranteeing the interconnect function of the interconnect chip. Correspondingly, the interconnect chip only includes an interconnect structural layer. One face of the interconnect structural layer opposite to the first chip and the chipset is used as the bonding face, and one face of the interconnect structural layer facing away from the first chip and the chipset is used as the back face.

It would be appreciated that the thickness of the interconnect chip 30 should not be too small or too large. If the thickness of the remaining interconnect chip 30 is too small, the thickness for which the back face 302 of the interconnect chip 30 is thinned is too large, which can increase the risk of damage to the interconnect structural layer. If the thickness of the remaining interconnect chip 30 is too large, the thickness for which the back face of the interconnect chip 30 is thinned is too small, which easily leads to a less significant effect of reducing the thickness of the interconnect chip 30. To this end, in this implementation, the interconnect chip 30 has a thickness of 2 μm to 15 μm.

In this implementation, the packaging structure further includes: first conductive bumps 11, located between the first chip 10 and the interconnect chip 30 and between the chipset 200 and the interconnect chip 30.

The first conductive bumps 11 are configured to bond the first chip 10 and the interconnect chip 30 and bond the chipset 200 and the interconnect chip 30. Specifically, in this implementation, the first conductive bumps 11 are located between the bottom chip 20a of the chipset 200 and the interconnect chip 30 to electrically connect the bottom chip 20a and the interconnect chip 30.

In this implementation, materials of the first conductive bump 11 include one or more of tin, copper, aluminum, tungsten, cobalt, nickel, titanium, tantalum, titanium nitride, and tantalum nitride. In an example, the material of the first conductive bump 11 is tin.

In this implementation, the packaging structure further includes a first sealing layer 305. The first sealing layer is located between the first chip 10 and the interconnect chip 30 and between the chipset 200 and the interconnect chip 30, and seals the first conductive bumps 11.

The first sealing layer 305 fills gaps between the first chip 10 and the interconnect chip 30 and gaps between the chipset 200 and the interconnect chip 30 to seal the first conductive bumps 11.

In an example, a material of the first sealing layer 305 is epoxy resin.

In this implementation, the packaging structure further includes second conductive bumps 12. The second conductive bumps 12 are located on the second face 102 and the fourth face 204 exposed from the interconnect chip 30, and are electrically connected to the first chip 10 and the chipset 200 respectively, and the height of the second conductive bump 12 is equal to or greater than that of the back face of the interconnect chip 30.

The second conductive bump 12 is configured to electrically connect the first chip 10 and the packaging substrate and electrically connect the chipset 200 and the packaging substrate.

More specifically, in this implementation, the second conductive bumps 12 are located on the bottom chip 20a exposed from the interconnect chip 30 and are electrically connected to the bottom chip 20a, thereby electrically connecting the bottom chip 20a and the packaging substrate by the second conductive bumps 12.

The height of the second conductive bump 12 is equal to or greater than that of the back face 302 of the interconnect chip 30, thereby avoiding the influence of the interconnect chip 30 on the bonding between the first chip 10 and the packaging substrate, and the bonding between the chipset 200 and the packaging substrate. Moreover, the height of the interconnect chip 30 is equal to or less than that of the second conductive bump 12, the back face 302 of the interconnect chip 30 is thinned, and the height of the interconnect chip 30 is less, which is also conducive to reducing the height of the second conductive bump 12, thus reducing the distance between the first chip 10 and the packaging substrate, and the distance between the chipset 200 and the packaging substrate, and improving the interconnect performance between the first chip 10 and the packaging substrate and the interconnect performance between the chipset 200 and the packaging substrate.

In this implementation, the second conductive bump 12 is a solder ball. As an implementation, a material of the solder ball includes tin.

Specifically, the solder ball is C4 (Controlled Collapse Chip Connection), which has excellent electrical and thermal properties. Moreover, under same solder ball spacing, the I/O quantity of C4 can be very high. In addition, the solder ball is also suitable for mass production, and the size and the weight are significantly reduced.

In other implementations, materials of the second conductive bump include one or more of tin, copper, aluminum, tungsten, cobalt, nickel, titanium, tantalum, titanium nitride, and tantalum nitride.

In this implementation, the packaging structure further includes a packaging substrate 300, bonded onto the second face 102 and the fourth face 204 exposed from the interconnect chip.

The packaging substrate 300 is configured to implement packaging integration and electrical integration between the chipset 200 and the first chip 10.

In this implementation, the packaging substrate 300 is a printed circuit board (PCB).

Specifically, in this implementation, the first chip 10 and the packaging substrate 300 are bonded and the chipset 200 and the packaging substrate 300 are bonded by the second conductive bumps 12.

In this implementation, the packaging structure further includes a second sealing layer 205. The second sealing layer 205 is located between the second face 102 of the first chip 10 and the packaging substrate 300 and between the fourth face 204 of the chipset 200 and the packaging substrate 300, and seals the second conductive bumps 12.

The second sealing layer 205 fills gaps between the second face 102 of the first chip 10 and the packaging substrate 300 and gaps between the fourth face 204 of the chipset 200 and the packaging substrate 300 to seal the second conductive bumps 12.

In an example, a material of the second sealing layer 205 is epoxy resin.

In this implementation, the packaging structure further includes fourth conductive bumps 340. The fourth conductive bumps are located on the surface of one side of the packaging substrate 300 facing away from the first chip 10 and the chipset 200, and is configured to electrically connect the packaging substrate 300 and an external circuit, thus electrically connecting the packaging structure and the external circuit.

In this implementation, the fourth conductive bump 340 is a solder ball. In an example, the material of the fourth conductive bump 340 is tin.

The packaging structure can be formed by the packaging method provided in the implementations of the present disclosure, and can also be formed by other methods.

Correspondingly, the present disclosure further provides a packaging method. FIG. 2 to FIG. 13 are schematic structural diagrams corresponding to all steps in an implementation of a packaging method of the present disclosure.

The packaging method in this implementation will be explained in details below in conjunction with the accompanying drawings.

Referring to FIG. 2, a bearing substrate 100 is provided. The bearing substrate 100 includes a bearing face 100a.

The bearing substrate 100 is configured to provide a process operating platform for subsequent bonding of the chipset and the first chip.

Specifically, the bearing face 100a is configured to bear the chipset and the first chip subsequently.

In this implementation, the bearing substrate 100 is a carrier wafer. In other implementations, the bearing substrate may also be other types of substrates. In this implementation, a material of the bearing substrate 100 may include one or more of silicon, glass, silicon oxide, and aluminum oxide.

Referring to FIG. 3, a first chip 10 is provided, including a first face 101 and a second face 102 that is opposite to the first face 101.

The first chip 10 is configured to be subsequently attached onto the bearing substrate 100, and is electrically connected to the chipset by an interconnect chip.

In this implementation, the first chip 10 is a first logic chip, configured to perform logic control over the chipset. Specifically, the first logic chip may be a central processing unit (CPU) chip, a graphics processing unit (GPU) chip, or a system on chip (SoC) chip.

In this implementation, the first face 101 is the back face of the first chip 10, and the second face 102 is the front face of the first chip 10. The front face of the first chip 10 refers to a face that a device in the first chip 10 faces, and the back face of the first chip 10 refers to a face that the device in the first chip 10 faces away from.

In this implementation, one or more metal layers (not shown in the figure) are formed on the front face of the first chip 10 in order that the interconnect chip is subsequently bonded on the front face of the first chip 10, and the bonding face of the interconnect chip is opposite to the second face 102, and the interconnect chip can be electrically connected to the first chip 10 by the metal layer(s) on the second face 102 of the first chip 10.

Referring to FIG. 4, a chipset 200 is provided. The chipset 200 includes a third face 203 and a fourth face 204 that is opposite to the third face 203. The chipset 200 includes a plurality of second chips 20 stacked in a direction perpendicular to the bearing substrate 100, and is electrically connected between adjacent second chips 20 in the direction perpendicular to the bearing substrate 100.

The chipset 200 is configured to be subsequently attached onto the bearing face 100a, and is subsequently bonded with the interconnect chip, and thus, the chipset 200 and the first chip are electrically connected by the interconnect chip, thereby forming a corresponding packaging structure to implement corresponding functions.

Specifically, in this implementation, the third face 203 is configured to be subsequently attached onto the bearing face 100a, and the fourth face 204 is configured to be bonded with the interconnect chip, and thus, the chipset 204 and the interconnect chip are electrically connected.

In this implementation, in the chipset 200, a plurality of second chips 20 stacked in a longitudinal direction (i.e., the direction perpendicular to the bearing substrate 100) constitute a high bandwidth memory (HBM) structure. The HBM structure is employed, which is conducive to meeting the requirements for a higher information transmission rate.

In this implementation, adjacent second chips 20 in the direction perpendicular to the bearing substrate 100 are electrically connected, thereby implementing electrical integration with the second chips 20.

Specifically, in this implementation, third conductive bumps 13 are formed between adjacent second chips 20 in the direction perpendicular to the bearing substrate 100, and the adjacent second chips 20 are electrically connected by the third conductive bumps 13.

In this implementation, materials of the third conductive bump 13 include one or more of tin, copper, aluminum, tungsten, cobalt, nickel, titanium, tantalum, titanium nitride, and tantalum nitride. In an example, the material of the third conductive bump 13 is tin.

In this implementation, in the chipset 200, the second chip 20 closest to the fourth face 204 is used as a bottom chip 20a, and the remaining second chips 20 is used as top chips 20b.

In this implementation, the bottom chip 20a is a second logic chip, configured to control the top chips 20b.

In this implementation, the top chip 20b is a storage chip, e.g., a DRAM chip. In this implementation, the quantity of the top chips 20b may be one or more. In this implementation, it is illustrated with the quantity of the top chips 20b being four. In other implementations, the top chips may also be in other quantities.

Specifically, in this implementation, the bottom chip 20a is used as a logic control chip in the chipset 200, thereby controlling the storage chip.

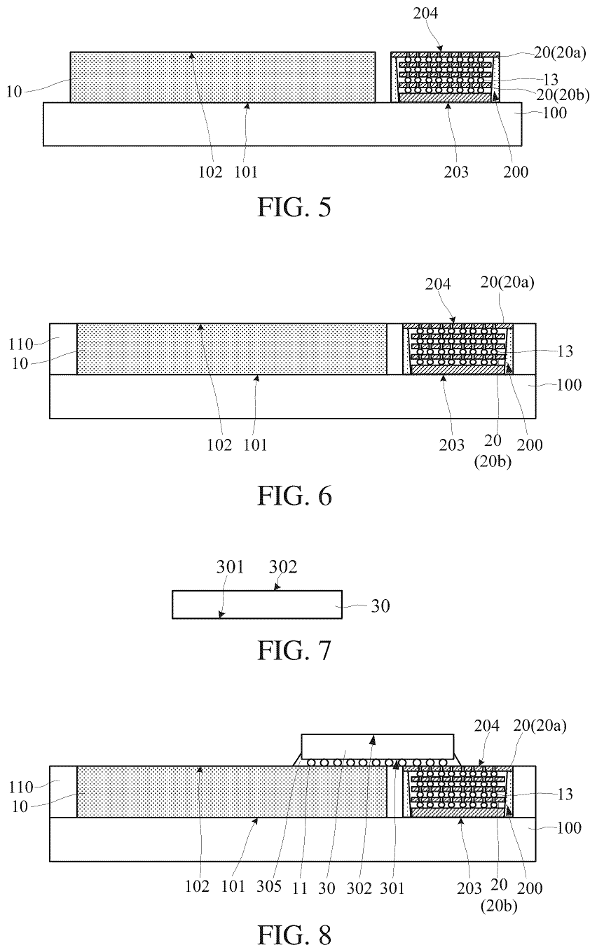

Referring to FIG. 5, the first chip 10 is attached onto the bearing substrate 100, and the first face 101 is opposite to the bearing face 100a.

The first chip 10 is attached onto the bearing substrate 100 in order that packaging integration between the first chip 10 and the chipset 200 can be implemented after the chipset 200 is attached onto the bearing substrate 100.

The first face 101 is opposite to the bearing face 100a, that is, the second face 102 of the first chip 10 faces away from the bearing face 100a, and the second face 102 is exposed from the bearing substrate 100 in order that the interconnect chip is subsequently bonded on the second face 102, thus electrically connecting the interconnect chip and the first chip 10.

In a specific implementation, the first chip 10 can be attached onto the bearing substrate 100 in a manner of temporary bonding in order that the difficulty of subsequently removing the bearing substrate 100 is lowered.

Referring to FIG. 5, the chipset 200 is attached onto the bearing substrate 100 and the third face 203 is opposite to the bearing face 100a.

The chipset 200 is attached onto the bearing substrate 100 in order that packaging integration between the first chip 10 and the chipset 200 can be implemented after the first chip 10 is attached onto the bearing substrate 100.

In this implementation, the third face 203 is opposite to the bearing face 100a, that is, the fourth face 204 of the chipset 200 faces away from the bearing face 100a, and the fourth face 204 is exposed from the bearing substrate 100 in order that the interconnect chip is subsequently bonded on the fourth face 204, thus electrically connecting the interconnect chip and the chipset 200, and electrically connecting the chipset 200 and the first chip 10 by the interconnect chip.

In a specific implementation, the chipset 200 can be attached onto the bearing substrate 100 in a manner of temporary bonding in order that the difficulty of removing the bearing substrate 100 subsequently is lowered.

Referring to FIG. 6, in this implementation, the packaging method further includes the following: after the first chip 10 is attached onto the bearing substrate 100 and the chipset 200 is attached onto the bearing substrate 100, and before the interconnect chip is bonded on the first chip 10 and the chipset 200, a packaging layer 110 is formed on the bearing face 100a on side portions of the first chip 10 and the chipset 200. The packaging layer 110 covers side walls of the first chip 10 and the chipset 200, and the second face 102 and the fourth face 204 are exposed.

The packaging layer 110 is configured to implement packaging integration between the first chip 10 and the chipset 200. The packaging layer 110 may also play a role of insulation, sealing, and moisture proofing, which is conducive to improving the reliability of the packaging structure. The packaging layer 110 is further configured to provide a process platform for subsequent bonding of the interconnect chip.

The second face 102 and the fourth face 204 are exposed from the packaging layer 110 in order that the interconnect chip can be bonded on the second face 102 of the first chip 10 and the fourth face 204 of the chipset 200, so that the interconnect chip is electrically connected to the first chip, and the interconnect chip is electrically connected to the chipset 200, and thus, the first chip 10 and the chipset 200 are electrically connected by the interconnect chip.

As an implementation, a material of the packaging layer 110 is a molding material, e.g., epoxy resin. The epoxy resin has the advantages such as low shrinkage, good adhesion, good corrosion resistance, excellent electrical performance, and low cost. In other implementations, other suitable packaging materials may also be selected for the packaging layer.

In an example, a step of forming a packaging layer 110 includes the following: a packaging material layer (not shown in the figure) is formed on the bearing substrate 100 to cover the first chip 10 and the chipset 200; and the packaging material layer exceeding the second face 102 of the first chip 10 and the fourth face 204 of the chipset 200 is removed. The remaining packaging material layer covering side walls of the first chip 10 and the chipset 200 is used as the packaging layer 110.

In an example, the packaging material layer is formed by employing a molding process. In other implementations, based on actual process requirements, the packaging material layer can be formed also by employing other suitable processes.

In an example, the packaging material layer exceeding the second face 102 of the first chip 10 and the fourth face 204 of the chipset 200 is removed by employing a grinding process, thereby improving the flatness of the top face of the packaging layer 110, which is thus conducive to a subsequent process and provides a flat surface for subsequent bonding of the interconnect chip.

Referring to FIG. 7, an interconnect chip 30 is provided. The interconnect chip 30 includes a bonding face 301 and a back face 302 facing away from the bonding face 301.

The interconnect chip 30 is provided in order that the interconnect chip 30 is subsequently bonded onto the first chip 10 and the chipset 200, and thus, the first chip 10 and the chipset 200 are interconnected.

Specifically, the interconnect chip 30 is used as a bridge, configured to interconnect the first chip 10 and the chipset 200.

The bonding face 301 is configured to be subsequently bonded with the first chip 10 and the chipset 200, and thus, the first chip 10 and the chipset 200 are electrically connected by the interconnect chip 30.

The back face 302 is thinned subsequently in order to thin the thickness of the interconnect chip 30.

In this implementation, the interconnect chip 30 includes a substrate layer (not shown in the figure) and an interconnect structural layer (not shown in the figure) located thereon. One face of the substrate layer facing away from the interconnect structural layer is used as the back face 302, and one face of the interconnect structural layer facing away from the substrate layer is used as the bonding face 301.

In this implementation, the substrate layer is configured to provide support for the formation of an interconnect structural layer, and in a step of subsequently thinning the back face 302 of the interconnect chip 30, the substrate layer is thinned.

The substrate layer is thinned, thereby thinning the thickness of the interconnect chip 30 while it is guaranteed that the interconnect chip 30 implements the interconnect performance between the first chip 10 and the chipset 200.

In this implementation, a material of the substrate layer is silicon.

The interconnect structural layer is configured to electrically connect the first chip 10 and the chipset 200 subsequently.

In an example, the interconnect structural layer is a rewiring structural layer. The rewiring structural layer can redistribute a connection end of the interconnect chip in order that first conductive bumps with density and position that meets the process requirements are formed, in order that the first chip 10 and the interconnect chip 30 are electrically connected subsequently as well as the chipset 200 and the interconnect chip 30 by the first conductive bumps. Moreover, the spacing between the first conductive bumps is relatively small and the density is relatively high, which is conducive to improving the interconnect performance between the first chip 10 and the interconnect chip 30 and the interconnect performance between the chipset 200 and the interconnect chip 30, thus improving the interconnect performance between the first chip and the chipset 200.

Correspondingly, in this implementation, the interconnect structural layer is also configured to provide a process platform for the formation of first conductive bumps.

Specifically, the rewiring structural layer may include one or more rewiring layers. Specifically, a material of the rewiring layer is a conductive material. In an example, a material of the rewiring structure layer is metal, including any one or more of copper, titanium, aluminum, gold, nickel, iron, tin, silver, zinc, or chromium.

Referring to FIG. 8, the interconnect chip 30 is bonded on the first chip 10 and the chipset 200. The bonding face 301 is opposite to the second face 102 and the fourth face 204, and the interconnect chip 30 is electrically connected to the chipset 200 and the first chip 10, and thereby the interconnect chip 30 is used as a bridge to electrically connect the chipset 200 and the first chip 10.

Specifically, in this implementation, in a step of bonding the interconnect chip 30 on the first chip 10 and the chipset 200, the interconnect chip 30 is bonded on the first chip 10, the chipset 200, and the packaging layer 110.

More specifically, in this implementation, in the chipset 200, the bottom chip 20a is bonded with the interconnect chip 30, and thereby, the bottom chip 20a is electrically connected to the interconnect chip 30. Moreover, adjacent second chips 20 are electrically connected, and thereby, the top chip 20b can be electrically connected to the interconnect chip 30 by the bottom chip 20a.

In this implementation, a step of bonding the interconnect chip 30 on the first chip 10 and the chipset 200 includes the following: first conductive bumps 11 is formed between the first chip 10 and the interconnect chip 30 and between the chipset 200 and the interconnect chip 30, and the first chip 10 and the interconnect chip 30 are bonded and the chipset 200 and the interconnect chip 30 are bonded by the first conductive bumps 11.

Specifically, in this implementation, the first conductive bumps 11 are located between the bottom chip 20a of the chipset 200 and the interconnect chip 30 to electrically connect the bottom chip 20a and the interconnect chip 30.

In this implementation, materials of the first conductive bump 11 include one or more of tin, copper, aluminum, tungsten, cobalt, nickel, titanium, tantalum, titanium nitride, and tantalum nitride. In an example, the material of the first conductive bump 11 is tin.

In a specific implementation, first conductive bumps 11 can be formed on the bonding face 301 of the interconnect chip 30; or, first conductive bumps can be formed on the second face 102 of the first chip 10 and the fourth face 204 of the chipset 200. Afterwards, the first chip 10 and the interconnect chip 30 are bonded and the chipset 200 and the interconnect chip 30 are bonded by the first conductive bumps 11.

It would be appreciated that in this implementation, the interconnect chip 30 is bonded onto partial top faces of the first chip 10 and the chipset 200 adjacent to the first chip 10, that is, a partial surface of the second face 102 and a partial surface of the fourth face 204 are also exposed from the interconnect chip 30 in order that the second face 102 and the fourth face 204 exposed from the interconnect chip 30 are bonded with the packaging substrate, thus electrically connecting the first chip 10 and the packaging substrate and electrically connecting the chipset 200 and the packaging substrate.

More specifically, the second face 102 and the fourth face 204 exposed from the interconnect chip 30 are configured to arrange second conductive bumps in order that the second face and the fourth face are bonded with the packaging substrate by the second conductive bumps.

In this implementation, the packaging method further includes the following: after the first chip 10 and the interconnect chip 30 are bonded and the chipset 200 and the interconnect chip 30 are bonded by the first conductive bumps 11, a first sealing layer 305 that seals the first conductive bumps 11 is formed between the first chip 10 and the interconnect chip 30 and between the chipset 200 and the interconnect chip 30.

The first sealing layer 305 fills gaps between the first chip 10 and the interconnect chip 30 and gaps between the chipset 200 and the interconnect chip 30 to seal the first conductive bumps 11.

In an example, the first sealing layer 305 is formed by employing an underfill process.

In an example, a material of the first sealing layer 305 is epoxy resin.

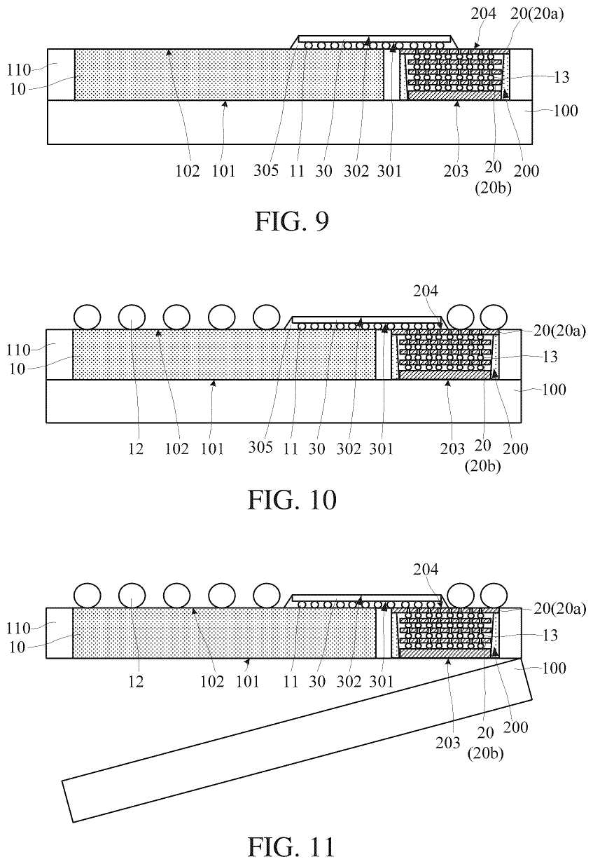

Referring to FIG. 9, after the interconnect chip 30 is bonded on the first chip 10 and the chipset 200, the back face 302 of the interconnect chip 30 is thinned.

The back face 302 of the interconnect chip 30 is thinned, thereby reducing the thickness of the interconnect chip 30, which is conducive to simplifying the packaging structure and thinning of a device, and after the packaging structure is subsequently bonded onto the packaging substrate, the interconnect chip 30 is thinner, which is conducive to shortening the distance between the first chip 10 and the packaging substrate and the distance between the chipset 200 and the packaging substrate, thus facilitating heat dissipation of the packaging structure and improving the performance of the packaging structure.

In this implementation, after the interconnect chip 30 is bonded on the first chip 10 and the chipset 200, the back face 302 of the interconnect chip 30 is thinned, and the interconnect chip 30 is fixed onto the first chip 10 and the chipset 200, which is conducive to thinning the interconnect chip 30 to a thickness required by the process, thus facilitating thinning of the interconnect chip 30 and the packaging structure.

In this implementation, in a step of thinning the back face 302 of the interconnect chip 30, the substrate layer is thinned.

In a specific implementation, in a step of thinning the substrate layer, the substrate layer can be removed, thereby further reducing the thickness of the interconnect chip 30, so that only the interconnect structural layer is retained in the interconnect chip 30, thereby guaranteeing the interconnect function of the interconnect chip 30; or, the substrate layer is removed for a partial thickness to reduce the probability of damage to the interconnect structural layer, thus reducing process risks.

In this implementation, after the back face 302 of the interconnect chip 30 is thinned, the thickness of the remaining interconnect chip 30 should not be too small or too large. If the thickness of the remaining interconnect chip 30 is too small, the thickness for which the back face 302 of the interconnect chip 30 is thinned is too large, which can increase the risk of damage to the interconnect structural layer. If the thickness of the remaining interconnect chip 30 is too large, the thickness for which the back face of the interconnect chip 30 is thinned is too small, which easily leads to a less significant effect of reducing the thickness of the interconnect chip 30. To this end, in this implementation, after the back face 302 of the interconnect chip 30 is thinned, the remaining interconnect chip 30 has a thickness of 2 μm to 15 μm.

In this implementation, the back face 302 of the interconnect chip 30 is thinned by employing an etching process. The precision of the etching process is high, which is conducive to improving the control accuracy of the thickness for thinning and reducing the probability of damage to the interconnect structural layer or other film layer structures.

In an example, the etching process may include an anisotropic dry etching process. The anisotropic dry etching process has high etching accuracy and a fast etching rate.

In other implementations, the etching process may also be a wet etching process, or a combination of a dry etching process and the wet etching process.

Referring to FIG. 10, in this implementation, after the thinning, and before removing the bearing substrate 100, second conductive bumps 12 are formed on the second face 102 and the fourth face 204 exposed from the interconnect chip 30. The second conductive bumps 12 are electrically connected to the first chip 10 and the chipset 200 respectively, and the height of the second conductive bump 12 is equal to or greater than that of the back face 302 of the interconnect chip 30.

Subsequent steps further include the following: a packaging substrate is provided. The second face 102 of the first chip 10 and the fourth face 204 of the chipset 200 are bonded onto the packaging substrate. The second conductive bump 12 is configured to electrically connect the first chip 10 and the packaging substrate, and electrically connect the chipset 200 and the packaging substrate.

More specifically, in this implementation, the second conductive bumps 12 are located on the bottom chip 20a exposed from the interconnect chip 30 and are electrically connected to the bottom chip 20a, thereby electrically connecting the bottom chip 20a and the packaging substrate by the second conductive bumps 12.

The height of the second conductive bump 12 is equal to or greater than that of the back face 302 of the interconnect chip 30, thereby avoiding the influence of the interconnect chip 30 on the bonding process in a step of subsequently bonding the second face 102 of the first chip 10 and the fourth face 204 of the chipset 200 onto the packaging substrate. Moreover, the height of the interconnect chip 30 is equal to or less than that of the second conductive bump 12, the back face 302 of the interconnect chip 30 is thinned, and the height of the interconnect chip 30 is less, which is also conducive to reducing the height of the second conductive bump 12, thus reducing the distance between the first chip 10 and the packaging substrate, and the distance between the chipset 200 and the packaging substrate, and improving the interconnect performance between the first chip 10 and the packaging substrate and the interconnect performance between the chipset 200 and the packaging substrate.

In this implementation, the second conductive bump 12 is a solder ball. As an implementation, a material of the solder ball includes tin.

Specifically, the solder ball is C4 (Controlled Collapse Chip Connection), which has excellent electrical and thermal properties. Moreover, under same solder ball spacing, the I/O quantity of C4 can be very high. In addition, the solder ball is also suitable for mass production, and the size and the weight are significantly reduced.

In other implementations, materials of the second conductive bump include one or more of tin, copper, aluminum, tungsten, cobalt, nickel, titanium, tantalum, titanium nitride, and tantalum nitride.

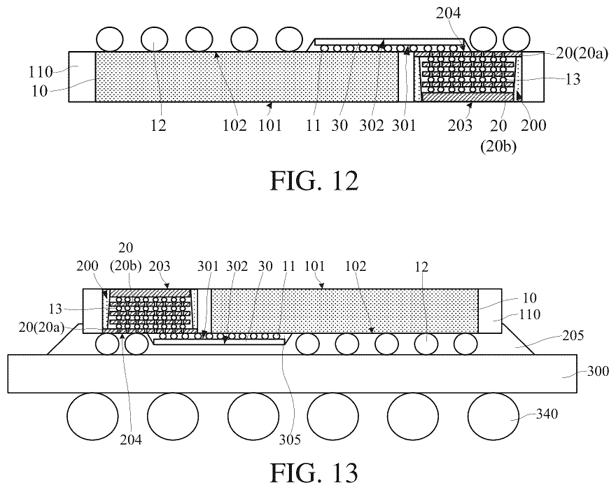

Referring to FIG. 11 and FIG. 12, in this implementation, the packaging method further includes the following: the bearing substrate 100 is removed after the thinning in order that the second face 102 of the first chip 10 and the fourth face 204 of the chipset 200 are subsequently bonded onto the packaging substrate.

More specifically, in this implementation, after the second conductive bumps 12 are formed, the bearing substrate 100 is removed.

In an example, the bearing substrate 100 is removed by debonding, thereby reducing the difficulty of removing the bearing substrate 100.

Referring to FIG. 13, the packaging method further includes the following: a packaging substrate 300 is provided; and after removing the bearing substrate 100, the second face 102 of the first chip 10 and the fourth face 204 of the chipset 200 are bonded onto the packaging substrate 400.

The packaging substrate 300 is configured to implement packaging integration and electrical integration between the chipset 200 and the first chip 10.

In this implementation, the packaging substrate 300 is a printed circuit board (PCB).

Specifically, in this implementation, the first chip 10 and the chipset 200 are bonded with the packaging substrate 300 by the second conductive bumps 12.

In this implementation, the packaging method further includes the following: after the first chip 10 and the chipset 200 are bonded by the second conductive bumps 12, a second sealing layer 205 that seals the second conductive bumps 12 is further formed between the second face 102 of the first chip 10 and the packaging substrate 300 and between the fourth face 204 of the chipset 200 and the packaging substrate 300.

The second sealing layer 205 fills gaps between the second face 102 of the first chip 10 and the packaging substrate 300 and gaps between the fourth face 204 of the chipset 200 and the packaging substrate 300 to seal the second conductive bumps 12.

In an example, the second sealing layer 205 is formed by employing an underfill process.

In an example, a material of the second sealing layer 205 is epoxy resin.

In this implementation, the packaging method further includes the following: fourth conductive bumps 340 is formed on the surface of one side of the packaging substrate 300 facing away from the first chip 10 and the chipset 200, for electrically connecting the packaging substrate 300 and an external circuit.

In this implementation, the fourth conductive bump 340 is a solder ball. In an example, the material of the fourth conductive bump 340 is tin.

Although the present disclosure has been described as above, the present disclosure is not limited thereto. Any person skilled in the art can make various changes and modifications without departing from the spirit and scope of the present disclosure, so the scope of protection of the present disclosure shall be subject to the scope limited by the claims.

What is claimed is:

1. A packaging structure, comprising:
a first chip, comprising a first face and a second face that is opposite to the first face;
a chipset, wherein:
the chipset is located on a side portion of the first chip,
the chipset comprises a plurality of second chips stacked in a vertical direction, and is electrically connected between adjacent second chips in the vertical direction, and
the chipset comprises a third face and a fourth face that is opposite to the third face, and the first face and the third face face a same direction; and
an interconnect chip, wherein:
the interconnect chip comprises a bonding face and a back face facing away from the bonding face,
the interconnect chip is located on the first chip and the chipset, where the bonding face is opposite to the second face and the fourth face,
the interconnect chip is electrically connected to the chipset and the first chip, and
the back face of the interconnect chip is thinned.

2. The packaging structure according to claim 1, wherein:
the packaging structure further comprises a packaging layer, the packaging layer being located on side portions of the first chip and the chipset, and covering side walls of the first chip and the chipset.

3. The packaging structure according to claim 1, wherein:
the interconnect chip comprises a substrate layer and an interconnect structural layer located on the substrate layer, where one face of the substrate layer facing away from the interconnect structural layer is used as the back face, and where one face of the interconnect structural layer facing away from the substrate layer is used as the bonding face; or
the interconnect chip comprises an interconnect structural layer, wherein one face of the interconnect structural layer is opposite to the first chip and the chipset is used as the bonding face, and where one face of the interconnect structural layer facing away from the first chip and the chipset is used as the back face.

4. The packaging structure according to claim 3, wherein the interconnect structural layer is a rewiring structural layer.

5. The packaging structure according to claim 1, wherein the interconnect chip has a thickness of 2 μm to 15 μm.

6. The packaging structure according to claim 1, wherein the packaging structure further comprises:
first conductive bumps, located between the first chip and the interconnect chip and between the chipset and the interconnect chip.

7. The packaging structure according to claim 1, wherein the packaging structure further comprises:
second conductive bumps, wherein the second conductive bumps are located on the second face and the fourth face exposed from the interconnect chip, and are electrically connected to the first chip and the chipset respectively, and a height of the second conductive bump is equal to or greater than that of a back face of the interconnect chip.

8. The packaging structure according to claim 1, wherein the first chip is a logic chip, and the chipset is a high bandwidth memory chipset.

9. A packaging method, comprising:
providing a bearing substrate, wherein the bearing substrate comprises a bearing face;
providing a first chip, comprising a first face and a second face that is opposite to the first face;
providing a chipset, wherein the chipset comprises a third face and a fourth face that is opposite to the third face, where the chipset comprises a plurality of second chips stacked in a direction perpendicular to the bearing substrate, and is electrically connected between adjacent second chips in the direction perpendicular to the bearing substrate.
attaching the first chip onto the bearing substrate, wherein the first face is opposite to the bearing face;
attaching the chipset onto the bearing substrate, wherein the third face is opposite to the bearing face;
providing an interconnect chip, wherein the interconnect chip comprises a bonding face and a back face facing away from the bonding face;
bonding an interconnect chip on the first chip and the chipset, wherein the bonding face is opposite to the second face and the fourth face, and the interconnect chip is electrically connected to the chipset and the first chip; and
after bonding the interconnect chip on the first chip and the chipset, thinning the back face of the interconnect chip.

10. The packaging method according to claim 9, wherein:
in a step of providing the interconnect chip, the interconnect chip comprises a substrate layer and an interconnect structural layer located on the substrate layer, one face of the substrate layer facing away from the interconnect structural layer is used as the back face, and one face of the interconnect structural layer facing away from the substrate layer is used as the bonding face; and
in a step of thinning the back face of the interconnect chip, the substrate layer is thinned.

11. The packaging method according to claim 10, wherein in a step of thinning the substrate layer, the substrate layer is removed for at least a partial thickness.

12. The packaging method according to claim 10, wherein the interconnect structural layer is a rewiring structural layer.

13. The packaging method according to claim 9, further comprising:
forming a packaging layer on the bearing face on side portions of the first chip and the chipset after attaching the first chip onto the bearing substrate and attaching the chipset onto the bearing substrate, and before bonding the interconnect chip on the first chip and the chipset, the packaging layer covering side walls of the first chip and the chipset, and the second face and the fourth face being exposed; and
in a step of bonding the interconnect chip on the first chip and the chipset, the interconnect chip is bonded on the first chip, the chipset, and the packaging layer.

14. The packaging method according to claim 9, wherein a step of bonding the interconnect chip on the first chip and the chipset comprises:
forming first conductive bumps between the first chip and the interconnect chip and between the chipset and the interconnect chip;
bonding the first chip and the interconnect chip; and
bonding the chipset and the interconnect chip by the first conductive bumps.

15. The packaging method according to claim 9, wherein the back face of the interconnect chip is thinned by employing an etching process.

16. The packaging method according to claim 9, wherein after the back face of the interconnect chip is thinned, the remaining interconnect chip has a thickness of 2 μm to 15 μm.

17. The packaging method according to claim 9, further comprising:
removing the bearing substrate after the thinning.

18. The packaging method according to claim 17, further comprising:
forming second conductive bumps on the second face and the fourth face exposed from the interconnect chip after the thinning and before removing the bearing substrate,
wherein the second conductive bumps are electrically connected to the first chip and the chipset respectively, and a height of the second conductive bump is equal to or greater than that of the back face of the interconnect chip.

19. The packaging method according to claim 17, further comprising:
providing a packaging substrate; and
after removing the bearing substrate, bonding the second face of the first chip and the fourth face of the chipset onto the packaging substrate.

20. The packaging method according to claim 9, wherein the first chip is a logic chip, and the chipset is a high bandwidth memory chipset.
